(19) United States
(12) Patent Application Publication
(10) Pub. No.: US 2013/0027030 A1
(43) Pub. Date: Jan. 31, 2013

(54) FIBER OPTIC MAGNETIC FLUX SENSOR FOR APPLICATION IN HIGH VOLTAGE GENERATOR STATOR BARS

(71) Applicants: Michael Twerdochlib, Oviedo, FL (US); Erik Abromitis, Orlando, FL (US)

(72) Inventors: Michael Twerdochlib, Oviedo, FL (US); Erik Abromitis, Orlando, FL (US)

(21) Appl. No.: 13/191,547

(22) Filed: Jul. 27, 2011

(51) Int. Cl. G01R 33/02

(52) U.S. Cl. 324/244.1

(57) ABSTRACT

A magnetic flux sensor for measuring the radial component of the magnetic flux impinging on a stator bar of a high voltage generator. The magnetic flux sensor includes a fiber Bragg grating formed in an optical fiber and enclosed within a magnetostrictive coating. The magnetostrictive coating responds to changes in magnetic flux by applying a strain on the fiber that changes the reflected wavelength of the Bragg grating that can be measured to provide a measurement of the flux. In one embodiment, one or more of the magnetic flux sensors is positioned directly within an insulating layer of the particular stator bar.

### BACKGROUND OF THE INVENTION

1. Field of the Invention

This invention relates generally to a fiber optic magnetic flux sensor for measuring the magnetic flux in a stator bar of a high voltage generator and, more particularly, to a fiber optic magnetic flux sensor employing a magnetostrictive Bragg grating (MBG) provided within a fiber for measuring the radial component of the magnetic flux impinging on a stator bar of a high voltage generator.

2. Discussion of the Related Art

High voltage generators for generating electricity as a power source are well known in the art. A power plant may include gas turbine engines that each rotate a shaft by combusting fuel and air in a combustion chamber that expands across blades which rotate, and in turn causes the shaft to rotate. The output shaft of such an engine is coupled to an input shaft of a high voltage generator that is mounted to a rotor having a special configuration of coils. An electrical current provided in the rotor coils generates a magnetic flux around the coils, and as the rotor rotates, the magnetic flux interacts with windings in a stator core enclosing the rotor. The stator core windings include interconnected stator bars that have a special configuration to reduce eddy currents in the windings, which would otherwise generate significant heat and possibly damage various generator components.

It is generally necessary to determine the distribution of magnetic flux across the stator bars in a high voltage generator to more accurately calculate electrical losses, and therefore, more accurately model the overall losses of the stator windings. The usefulness of these measurements depends largely on how close the particular flux sensor can be placed relative to the stator bars since measurements obtained at increasing distances from the measurement location must be corrected for attenuation of the flux field over the distance from the sensor to the bars.

Monitoring the magnetic flux within large generators is typically accomplished using copper wire search coils inserted into the slots between stator teeth in which the stator bars are provided or mounted onto the stator coils. Search coils provided in the stator slots can be used to detect the presence of the radial flux that could give rise to circulating currents in the rotor that lead to losses in the stator windings. However, conductive copper coils tend to have large cross-sections that limit the ability to measure small flux areas, and thus provide an average measurement of local magnetic flux. Copper coils also provide a risk in that copper conductive leads can initiate a ground arc that can damage the stator windings.

It has been proposed in the art to employ fiber Bragg gratings (FBG) as sensors to measure strain, vibration and temperature for various applications. FBG sensors measure strain on an optical fiber at the Bragg grating locations. This strain slightly alters the spacing of reflective grating lines in the FBG, thus affecting its reflective property. A broadband infrared (IR) signal is transmitted through the optical fiber to the FBG sensor. The degree of strain on the FBG is measured by the wavelength of the IR radiation that is reflected from the FBG. As the strain spans the fiber Bragg lines, the wavelength of the reflected light is increased proportionately. As many as a hundred of such measurements can be provided on a single optical fiber by appropriately setting the spacing between the Bragg grating lines to prevent overlap in the reflected IR light from each Bragg grating. Such FBG systems can also operate in a transmission mode.

For an FBG sensor strain measurement, the FBG sensor is mechanically strained by bending the coil structure at the FBG sensor attachment locations. For an FBG sensor vibration measurement, a mass attached to the optical fiber alters the tension in the optical fiber as it responds to vibrations at the attachment site on the coil. For an FBG sensor temperature measurement, the thermal expansion of the Bragg grating itself changes the Bragg grating line spacing.

### SUMMARY OF THE INVENTION

In accordance with the teachings of the present invention, a magnetic flux sensor is disclosed that measures the radial component of the magnetic flux impinging on a stator bar of a high voltage generator. The magnetic flux sensor includes a fiber. Bragg grating formed in an optical fiber and enclosed within a magnetostrictive coating. The magnetostrictive coating responds to changes in magnetic flux by applying a strain on the fiber that changes the reflected wavelength of the Bragg grating that can be measured to provide a measurement of the flux. In one embodiment, one or more of the magnetic flux sensors are positioned directly within an insulating layer of the stator bar.

Additional features of the present invention will become apparent from the following description and appended claims, taken in conjunction with the accompanying drawings.

### BRIEF DESCRIPTION OF THE DRAWINGS

FIG. 1 is a cut-away, perspective view of a stator core for a high voltage generator;

FIG. 2 is a section view of the stator core shown in FIG. 1;

FIG. 3 is a schematic block diagram of a fiber Bragg grating detection system;

FIG. 4 is a block diagram of a fiber optic magnetic flux sensor system;

FIG. 5 is a side view of a magnetostrictive Bragg grating sensor in the flux sensor system;

FIG. 6 is a cross-sectional, broken-away view of a portion of a stator core showing magnetic flux sensors positioned within a slot relative to a stator bar; and

FIG. 7 is a section view of a stator bar including a plurality of stator bar strands and magnetic flux sensors positioned within a non-conductive filler layer underneath the main insulation layer of the stator bar.

### DETAILED DESCRIPTION OF THE EMBODIMENTS

The following discussion of the embodiments of the invention directed to an MBG sensor for measuring the radial component of the magnetic flux impinging on a stator bar of a high voltage generator is merely exemplary in nature, and is in no way intended to limit the invention or its applications or uses.

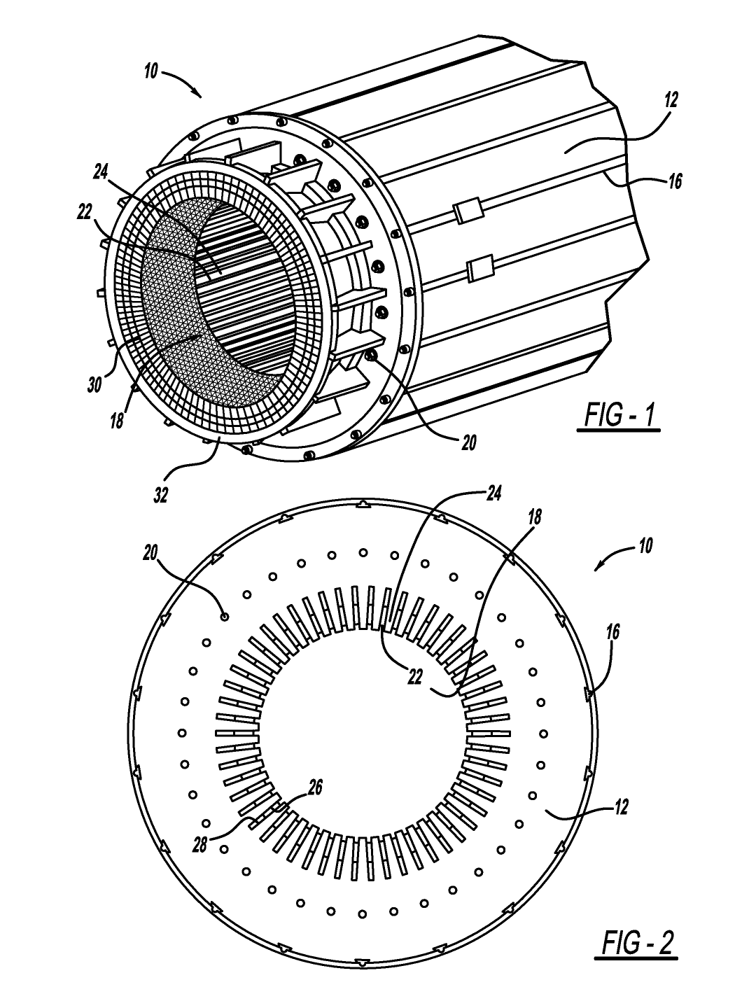

FIG. 1 is a cut-away perspective view and FIG. 2 is a section view of a stator core 10 for a high voltage generator. The stator core 10 includes a magnetic cylindrical portion 12 formed by an assembly of stacked thin, iron laminate sections aligned by key rods 16 and defining an internal bore 18. A series of through bolts 20 extend through the laminate sections to compress and hold the sections to form the cylindrical portion 12. The laminate sections of the cylindrical portion 12 define a series of circumferentially positioned slots 22 that are open to the bore 18 and define stator core teeth 24 therebetween. Electrically separated top and bottom stator bars 26 and 28, respectively, are provided within the slots 22, where each stator bar 26 and 28 extends the length of the cylindrical portion 12. As will be described in more detail below, each stator bar 26 and 28 includes a plurality of wound copper wire strands and an insulating member provided around the wire strands. The stator bars 26 and 28 are electrically coupled to each other to form three continuous windings, where stator end windings 30 at each end of the core 10 electrically couple the stator bars 26 and 28. An insulated support member 32 is mounted to each end of the core 10 and provides a support structure to hold the stator end windings 30 in place.

As will be discussed in detail below, the present invention proposes an MBG sensor including an FBG for measuring the magnetic flux in one or more of the slots 22 from the stator bars 26 and 28. The MBG sensors discussed herein are placed as close as possible to the wire strands in the stator bars 26 and 28 to provide an accurate flux measurement.

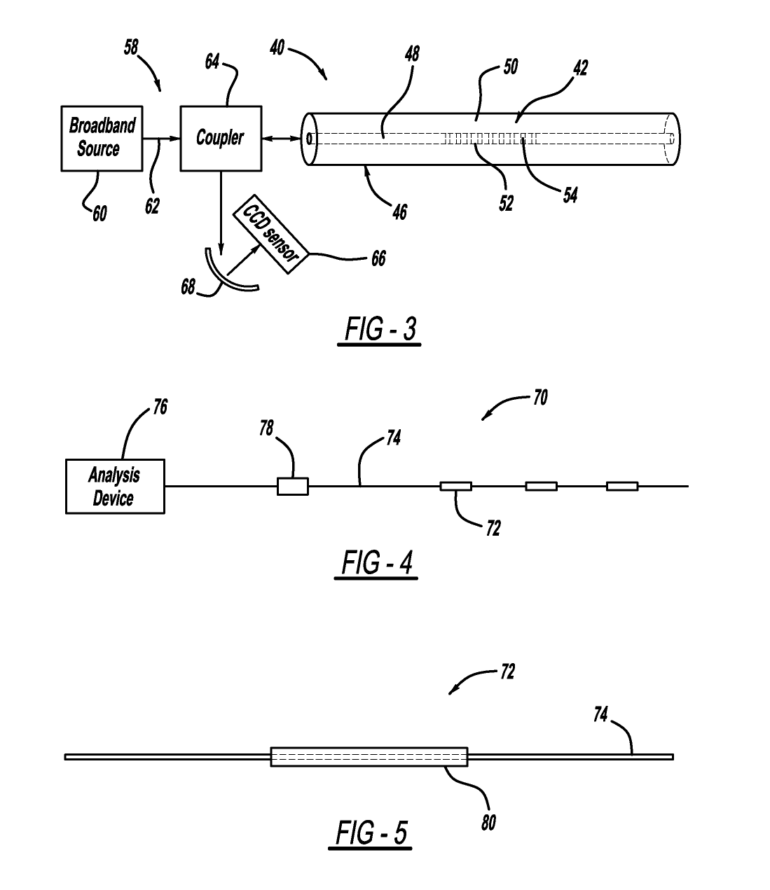

FIG. 3 is a schematic view of an FBG detection system 40 including an FBG sensor 42 formed in a section of an optical fiber 46. The optical fiber 46 includes an optical fiber core 48 surrounded by an outer cladding layer 50. The index of refraction of the cladding layer 50 is greater than the index of refraction of the fiber core 48 so that a light beam propagating down the fiber core 48 is reflected off of the transition between the fiber core 48 and the cladding layer 50 and is trapped therein. In one embodiment, the fiber core 48 is about 10 μm in diameter, which provides a multi-mode fiber for propagating multiple optical modes. The FBG sensor 42 is provided in the optical fiber 46 by creating an FBG 52 using a suitable optical writing process to provide a periodic pattern of sections 54 in the fiber core 48, where the sections 54 have a higher index of refraction than the rest of the fiber core 48, but a lower index of refraction than the cladding layer 50. For example, the index of refraction n₃ of the sections 54 is greater than the index of refraction n₂ of the fiber core 48 and the index of refraction n₃ of the sections 44 is less than the index of refraction n₁ of the cladding layer 50.

As is known by those skilled in the art, the FBG 52 can be selectively designed so that the index of refraction n₂ of the fiber core 48, the index of refraction n₃ of the sections 54, and the spacing Λ between the sections 54 define which wavelength λ_{B} is reflected by the FBG 52 based on equation (1) below.

λ_{B}=2n₃Λ (1)

The system 40 also includes a circuit 58 that generates the optical input signal and detects the reflected signal from one or more of the FBGs 52. The circuit 58 includes a broadband light source 60 that generates a light beam 62 that is passed through an optical coupler 64 and is directed into and propagates down the optical fiber 46 towards the FBG sensor 52. The light that is reflected by the FBG sensor 42 propagates back through the optical fiber 46 and is directed by the optical coupler 64 to a dispersive element 68 that distributes the various wavelengths components of the reflected beam to different locations on a linear charge-coupled sensor (CCD) 66, or some other suitable optical detector array, such as a Bragg oscilloscope. A system of optical filters can also be used to reduce system cost, while limiting the number of FBGs on the fiber 46. By providing the broadband source 60 and the dispersive element 68, more than one reflected wavelength λ_{B} can be detected by the CCD sensor 66, which allows more than one of the FBG sensors 42 to be provided within the fiber 46.

FIG. 4 is a block diagram of an MBG sensor system 70 including a plurality of MBG sensors 72 each having one or more fiber Bragg gratings, such as the FBG 52, formed in an optical fiber 74. It is noted that the Bragg grating portion of the fiber 74 is mechanically isolated from the stator bar material so that the thermal expansion of the bar does not induce strain on the sensor 72. The system 70 includes an analysis device 76, many of which are known in the art, such as a device based on the circuit 58 discussed above, that generates and transmits an optical input signal propagating down the fiber 74 and receives a reflected signal λ_{B} from the MBG sensors 72, whose wavelength depends on the strain in the fiber 74 at the particular location of the sensor 72. A pressure seal 78 is provided in the system 70 to show that the MBG sensors 72 may be inside of a pressure environment, such as may be necessary for measuring magnetic flux in the stator core 10. Each of the MBG sensors 72 reflects a different wavelength of light, and the strain on the fiber 74 alters the wavelength λ_{B} of that reflected light beam, which can be detected by the device 76.

The MBG sensors 72 each includes an outer layer of a magnetostrictive material that changes in shape in response to a magnetic flux that either increases or decreases the strain on the fiber 74 depending on the flux intensity, which can be measured as discussed above. FIG. 5 is a side view of one of the MBG sensors 72 in the fiber 74. The MBG sensor 72 includes an outer coating 80 of a magnetostrictive material that can be deposited on the fiber 74 by any suitable manner, such as vapor deposition. In one-limiting embodiment, the length of the sensor 72 is about 1.125 inches and the thickness of the sensor 72 is about 0.125 inches including the coating 80. Any suitable magnetostrictive material can be used for this purpose that is able to withstand the temperatures of a high voltage generator and is able to adequately be deposited on a very narrow fiber. The magnetostrictive material can be a bulk material, such as Terfenol-D, Galfenol, Metglas, etc., or a thin film material, such as Sm—Fe, Tb—Fe, FeTb, FeCo, etc. The MBG sensor 72 is calibrated by applying a known magnetic field to the sensor 72 and measuring the corresponding shift in the wavelength of the optical beam reflected by the FBG. In this manner, the device 76 is calibrated so that a particular change in the wavelength of the reflected signal represents a known change in the magnetic field.

A change in temperature of an FBG will change the spacing of the sections 54 in the FBG that alters the wavelength of the reflected signal. Based on this phenomenon, it is known to use FBG sensors to measure temperature to provide a temperature calibration. Once the MBG sensor 72 is calibrated for a particular magnetic flux, a change in temperature of the MBG sensor 72 will affect the flux measurement. Most applications for measuring the magnetic flux in a stator bar of a high voltage generator measures AC flux that alternates with time. An AC measurement will typically not require a compensation for temperature because a change in temperature will be an offset that is applied to all of the flux measurements as the signal osculates. However, for DC magnetic flux measurements, it typically will be necessary to know the temperature change of the MBG for an accurate measurement of the flux. Therefore, the present invention contemplates providing a second MBG sensor either in the same fiber 74 proximate to the MBG sensor 72 or in a separate fiber (not shown) adjacent to the MBG sensor 72. Therefore, as the temperature changes, and the temperature measuring FBG provides an indication of that temperature change, that temperature change can be used in the calibration to determine the DC magnetic flux being measured.

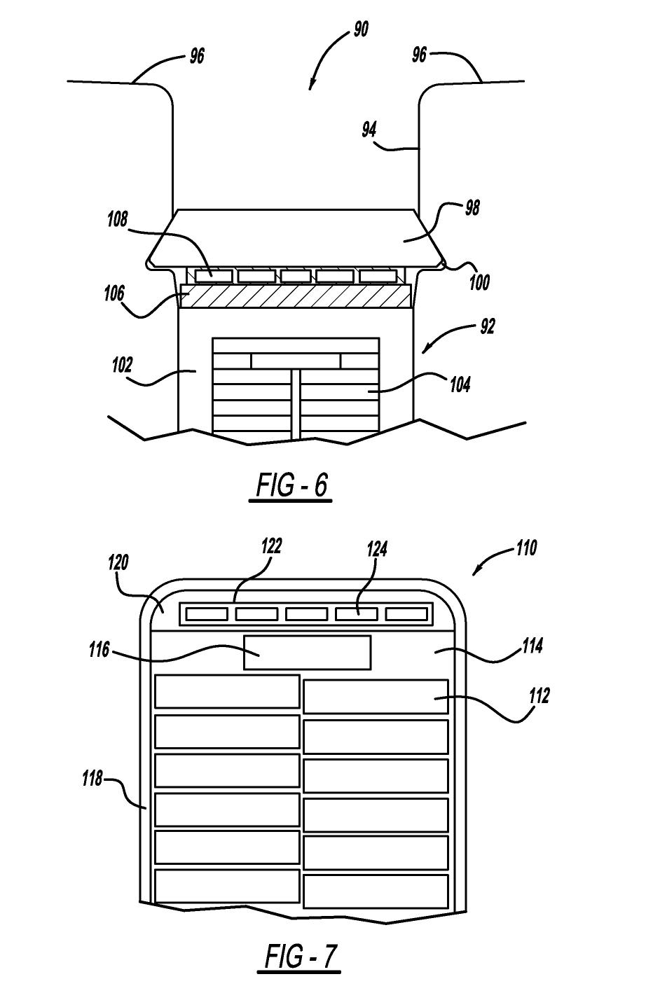

FIG. 6 is a cross-sectional, broken-away type view of a portion of a stator core 90 showing a stator bar 92, such as one of the stator bars 26 or 28, positioned within a slot 94, such as one of the slots 22, between two stator teeth 96, such as the teeth 24. The stator bar 92 is held within the slot 94 by a wedge 98 positioned within appropriate opposing openings 100 in the stator teeth 96. The stator bar 92 includes an outer insulation layer 102 enclosing a plurality of stator bar strands 104 each including copper wire strands enclosed by an insulating layer. The stator bar strands 104 are provided as sections of copper wire strands surrounded by an insulating layer and stacked in columns relative to each other to reduce any eddy currents within the stator bar 92 in a manner that is well understood by those skilled in the art. A wedge filler area 106 is provided between the wedge 98 and the stator bar 92 to provide spacing and stability for the stator bar 92.

According to the invention, one or more MBG sensors 108 of the type discussed above, are provided in the filler area 106 for measuring the magnetic flux of the stator bar 92 at a desired location. In this non-limiting example, five MBG sensors 108 are provided to measure the flux at specific locations across the slot 94. However, this is by way of a non-limiting example in that any suitable number of the MBG sensors 108 can be provided for a particular application for the desired flux measurement resolution. The sensors 108 can be part of any suitable detection system, as discussed above, where the sensors 108 can be provided in a single optical fiber, multiple optical fibers, etc., and where some of the sensors 108 can be provided for temperature measurement compensation. In this non-limiting embodiment, the sensors 108 are provided in only one of the slots 94 of the stator core 10 to provide the magnetic flux measurements. However, the MBG sensors 108 can be provided in any number of the slots 94 at any desirable location along the length of the stator core 10 as would be feasible.

Although the MBG sensors 108 are very close to the stator bar windings 104 that generate the magnetic flux, they can be positioned even closer to provide an even more accurate reading of the flux. FIG. 7 is a section view of a stator bar 110 including a plurality of stator bar strands 112 that are the same as or similar to the stator bar strands 104. The stator bar 110 would also be positioned within a slot of the stator bar. The stator bar strands 112 are positioned within a Roebel filler 114 that provides alignment, regularity and stability for the strands 112 in a manner that is well understood by those skilled in the art. A crimp winding 116 is provided within the Roebel filler 114 to also provide alignment for the stator strands 112 in a manner, that is well understood by those skilled in the art. The crimp winding 116 allows a proper electrical connection from one wire column to the next wire column. The stator bar 110 includes an inner corona protection layer 118 formed around the stator strands 112, which would be under the insulation layer 102 of the stator bar 92 discussed above. In the normal configuration for the stator bar 110 as shown, a profile strip 120 is provided at the top of the bar 120 between the protection layer 118 and the Roebel filler 114 and provides a non-conductive filler portion that conforms with the curvature of the protection layer 118. A cavity 122 is provided within the profile strip 120 to provide an opening for mounting one or more MBG sensors 124. Thus, in this configuration, the MBG sensors 124 are very close to the stator strands 112, and thus provide a highly accurate magnetic flux reading.

The foregoing discussion discloses and describes merely exemplary embodiments of the present invention. One skilled in the art will readily recognize from such discussion, and from the accompanying drawings and claims, that various changes, modifications and variations can be made therein without departing from the scope of the invention as defined in the following claims.

What is claimed is:

1. A magnetic flux sensor system for measuring magnetic flux in a stator core of a high voltage generator, said flux sensor system comprising:
at least one magnetostrictive Bragg grating (MBG) sensor positioned relative to at least one stator bar in the stator core, said at least one MBG sensor including a fiber Bragg grating (FBG) formed in an optical fiber and an outer coating of a magnetostrictive material; and
an analysis device providing an optical input signal to the optical fiber and receiving a reflected optical signal from the at least one MBG sensor, wherein the reflected optical signal provides a measurement of the magnetic flux from the stator bar.

2. The system according to claim 1 wherein the at least one MBG sensor is provided within a slot between stator teeth in the stator core.

3. The system according to claim 2 wherein the at least one MBG sensor is positioned between a wedge and the stator bar in a filler area.

4. The system according to claim 2 wherein the at least one MBG sensor is positioned in a profile strip within a protection layer provided around a plurality of stacked stator bar strands within the stator bar.

5. The system according to claim 1 wherein the coating of magnetostrictive material is a magnetostrictive bulk material.

6. The system according to claim 5 wherein the magnetostrictive bulk material is selected from the group consisting of Terfenol-D, Galfenol and Metglas.

7. The system according to claim 1 wherein the coating of magnetostrictive material is a thin film material.

8. The system according to claim 7 wherein the thin film material is selected from the group consisting of Sm—Fe, Tb—Fe, FeTb and FeCo.

9. The system according to claim 1 wherein the at least one MBG sensor is a plurality of MBG sensors spaced apart in the fiber, each MBG sensor reflecting an optical signal having a different wavelength.

10. The system according to claim 1 further comprising a temperature FBG sensor provided in association with the at least one MBG sensor for measuring temperature and providing a reflected temperature compensation optical signal.

11. The system according to claim 10 wherein the MBG sensor and temperature FBG sensor are provided in the fiber.

12. The system according to claim 10 wherein the MBG sensor and the temperature FBG sensor are provided in separate fibers.

13. A magnetic flux sensor system for measuring magnetic flux in a stator core of a high voltage generator, said flux sensor system comprising:
a plurality of magnetostrictive Bragg grating (MBG) sensors provided in a common optical fiber and spaced apart from each other, said plurality of MBG sensors each including a fiber Bragg grating (FBG) formed in the fiber and an outer coating of a magnetostrictive material, said plurality of MBG sensors being positioned within a slot between stator teeth in the stator core in proximity to a plurality of stacked stator bar strands; and
an analysis device providing an optical input signal to the optical fiber and receiving a reflected optical signal from each of the plurality of MBG sensors, where each MBG sensor reflects an optical signal having a different wavelength, and wherein the reflected optical signals provide a measurement of the magnetic flux from the stator bar.

14. The system according to claim 13 wherein the plurality of MBG sensors are positioned between a wedge and the stator bar in a filler area.

15. The system according to claim 13 wherein the plurality of MBG sensors are positioned in a profile strip within a protection layer provided around the plurality of stacked stator bar strands within the stator bar.

16. The system according to claim 13 further comprising a temperature FBG sensor provided in association with each MBG sensor for measuring temperature and providing a reflected temperature compensation optical signal.

17. A stator core for a high voltage generator, said stator core comprising:
a core portion having a central bore, a series of circumferentially disposed slots in communication with the bore and stator teeth between the slots;
at least one stator bar positioned within each slot in the core portion and being in electrical communication with each other and with stator end windings at ends of the stator core; and
at least one magnetostrictive Bragg grating (MBG) sensor provided within at least one of the slots, said at least one MBG sensor including a fiber Bragg grating (FBG) formed in an optical fiber and an outer coating of a magnetostrictive material.

18. The stator core according to claim 17 wherein the at least one MBG sensor is a plurality of MBG sensors provided in the at least one slot spaced apart from each other in the fiber, where each MBG sensor reflects an optical signal having a different wavelength.

19. The stator core according to claim 17 wherein the at least one MBG sensor is positioned between a wedge and the stator bar in a filler area.

20. The stator bar according to claim 17 wherein the at least one MBG sensor is positioned within a profile strip between stator bar strands and a protection layer within the stator bar.
